(19) United States
(12) Patent Application Publication
(10) Pub. No.: US 2018/0241005 A1
(43) Pub. Date: Aug. 23, 2018

(54) DISTRIBUTED BRAGG REFLECTOR ON COLOR CONVERSION LAYER WITH MICRO CAVITY FOR BLUE OLED LIGHTING APPLICATION

(71) Applicant: SABIC Global Technologies B.V., Bergen op Zoom (NL)

(72) Inventors: Sang Hoon KIM, Seoul (KR); Sung Min CHO, Gyeonggi-do (KR)

(21) Appl. No.: 15/760,763

(22) PCT Filed: Sep. 16, 2016
(86) PCT No.: PCT/IB2016/055556

§ 371 Date: Mar. 16, 2018

Related U.S. Application Data
(60) Provisional application No. 62/221,178, filed on Sep. 21, 2015.

(51) Int. Cl. H01L 51/52; H01L 27/32; H01L 51/00; H01L 51/56

(52) U.S. Cl. CPC H01L 51/5265; H01L 27/322; H01L 51/0097; H01L 51/5218; H01L 2251/558; H01L 51/56; H01L 2251/5338; H01L 2251/301; H01L 2251/303; H01L 51/5231

(57) ABSTRACT

A light emitting device and processes for making the same are disclosed. In an aspect, a light-emitting device comprises a substrate, an organic light emitting diode (OLED) disposed adjacent the substrate, the OLED configured to emit light having a wavelength at about 400 nm to about 480 nm, a color conversion layer disposed adjacent a side of the substrate opposite the OLED, and a distributed Bragg reflector (DBR) disposed adjacent the color conversion layer.

### RELATED APPLICATION

The present application claims priority to and the benefit of U.S. provisional application No. 62/221,178, titled “DISTRIBUTED BRAGG REFLECTOR ON COLOR CONVERSION LAYER WITH MICRO CAVITY FOR BLUE OLED LIGHTING APPLICATION,” and filed Sep. 21, 2015, the entirety of which is incorporated herein by reference for any and all purposes.

### TECHNICAL FIELD

The disclosure generally relates to organic light emitting devices (OLEDs), and more particularly to methods and structures utilizing a barrier substrate having distributed Bragg reflector (DBR) cavity function to enhance light extraction efficiency and high performance water vapor transmission rate (WVTR), for example.

### BACKGROUND

Organic light emitting devices (OLEDs) typically comprise a laminate formed on a substrate such as glass or silicon. A light-emitting layer of a luminescent organic solid, as well as optional adjacent semiconductor layers, is sandwiched between a cathode and an anode. The semiconductor layers may be hole-injecting or electron-injecting layers. The light-emitting layer may be selected from any of a multitude of fluorescent organic solids. The light-emitting layer may consist of multiple sub-layers or a single blended layer.

When a potential difference is applied across the anode and cathode, electrons move from the cathode to the optional electron-injecting layer and finally into the layer(s) of organic material. At the same time, holes move from the anode to the optional hole-injecting layer and finally into the same organic light-emitting layer(s). When the holes and electrons meet in the layer(s) of organic material, they combine, and produce photons. The wavelength of the photons depends on the material properties of the organic material in which the photons are generated. The color of light emitted from the OLED can be controlled by the selection of the organic material, or by the selection of dopants, or by other techniques known in the art. Different colored light may be generated by mixing the emitted light from different OLEDs. For example, white light can be produced by mixing blue, red, and green light.

In a typical OLED, either the anode or the cathode is transparent in order to allow the emitted light to pass through. If it is desirable to allow light to be emitted from both sides of the OLED, both the anode and cathode can be transparent.

The basic OLED has a structure in which an anode, an organic light emitting layer, and a cathode are consecutively laminated, with the organic light emitting layer sandwiched between the anode and the cathode. Generally, electrical current flowing between the anode and cathode passes through points of the organic light emitting layer and causes it to luminesce. The electrode positioned on the surface through which light is emitted is formed of a transparent or semi-transparent film. The other electrode is formed of a specific thin metal film, which can be a metal or an alloy.

OLEDs typically have a number of beneficial characteristics, including a low activation voltage (about 5 volts), fast response when formed with a thin light-emitting layer, high brightness in proportion to the injected electric current, high visibility due to self-emission, superior impact resistance, and ease of handling of the solid state devices in which they are used. OLEDs have practical application in television, graphic display systems, digital printing and lighting. Although substantial progress has been made in the development of OLEDs to date, additional challenges remain. For example. OLEDs continue to face challenges associated with their long-term stability. In particular, during operation the layers of organic film may undergo recrystallization or other structural changes that adversely affect the emissive properties of the device.

One of the factors limiting the widespread use of organic light emitting devices has been efficiency, which is determined by emitting materials. Among blue, red, and green organic emitting materials, blue shows lowest value in efficiency. Current value of blue emitting layer is about 10 cd/A. As such, a single blue emitting layer may not be sufficient for a lighting device.

Further, in OLED lighting application, a glass substrate has been used for its high performance property in WVTR (water vapor transmission rate, g/m2/day). However, glass is very fragile and difficult to be flexible. To realize design freedom in shape, it is necessary to use a substrate which is flexible. These and other shortcomings of the prior art are addressed by the present disclosure.

### SUMMARY

In accordance with one aspect of the disclosure, a light-emitting device comprises a substrate, an organic light emitting diode (OLED) disposed adjacent the substrate, the OLED configured to emit light having a wavelength at about 400 nm to about 480 nm, a color conversion layer disposed adjacent a side of the substrate opposite the OLED, and a distributed Bragg reflector (DBR) disposed adjacent the color conversion layer.

In accordance with another aspect of the disclosure, a process for fabricating an OLED assembly includes: forming an OLED structure, including providing a flexible substrate, providing an OLED on the flexible substrate, wherein the OLED comprises a first electrode, a second electrode and an organic electroluminescent layer disposed between the first and second electrodes; forming a color conversion layer adjacent a side of the flexible substrate opposite the OLED; and forming a distributed Bragg reflector (DBR) adjacent the color conversion layer.

### BRIEF DESCRIPTION OF THE DRAWINGS

The above-mentioned and other features and advantages of this disclosure, and the manner of attaining them, will become apparent and be better understood by reference to the following description of one aspect of the disclosure in conjunction with the accompanying drawings, wherein:

FIG. 1 is a plot of photoluminescence curves for various optical devices illustrating relative intensities vs. wavelength.

FIG. 2 is a plot of photoluminescence curves for various optical devices illustrating current efficiencies vs. current density.

FIG. 3 a schematic illustration of an OLED, according to an aspect of the disclosure.

FIG. 4 a schematic illustration of an OLED, according to an aspect of the disclosure.

FIG. 5 is a plot of transmittance curves for two types of DBR combinations illustrating transmittance percent vs. wavelength, according to aspects of the disclosure.

FIG. 6 is a plot of transmittance curves for two types of DBR combinations illustrating transmittance percent vs. wavelength, according to aspects of the disclosure.

FIG. 7 is a flow diagram of a process according to aspects of the disclosure.

### DETAILED DESCRIPTION

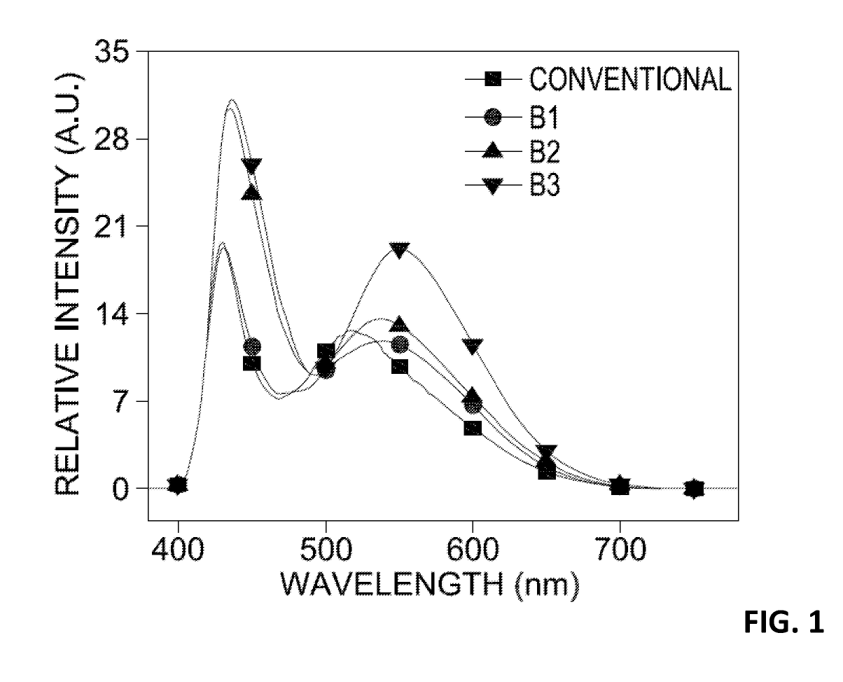

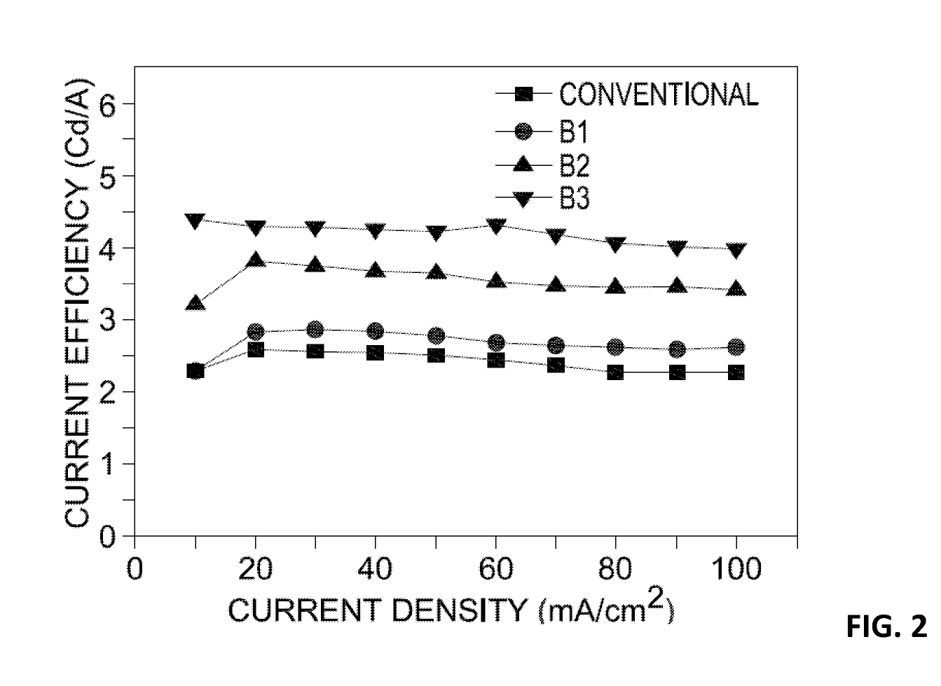

FIGS. 1 and 2 shows photoluminescence curves for light emitting devices including: Conventional OLED device: including blue, red, green emission layer with charge generation layers respectively (e.g., tandem structure); B1: Blue OLED+LRF+YAG:Ce; B2: Microcavity blue OLED+YAG:Ce; and B3: Microcavity blue OLED+LRF+YAG:Ce. As illustrated by the curves associated with B1 (e.g., a conventional phosphor-OLED is combined with a light-recycling filters (LRFs)), no improvement of luminous efficacy was observed. One of skill in the art will understand that the decreased effect of blue transmission of the conventional OLED reflected by the LRF may cancel the increased effect of forward emission recycled by the yellow reflection of LRF. As illustrated by the curves associated with B2 (e.g., an OLED combined with a moderate microcavity), the luminous efficacy is improved. One of skill in the art will understand that the improved efficacy may be due, at least in part, to the enhanced intensity and the narrowed spectrum of blue emission from the microcavity OLED source.

In an aspect, a blue OLED may be disposed adjacent an electrode formed from indium tin oxide (ITO) and a color-conversion-layer (CCL) film may be disposed on a side of a substrate opposite the OLED and electrode. Since the CCL film consist of only a single layer of phosphor (YAG:Ce), much of the emitted blue light passes through the phosphor without conversion. Further, almost half of the converted light by the CLL film is emitted backward and may be considered as loss. Additionally, the broad emission spectrum band of blue OLED light may not be sufficient to efficiently excite phosphor, resulting in overall low conversion efficiency. As such, other configurations of light emitting devices may be considered.

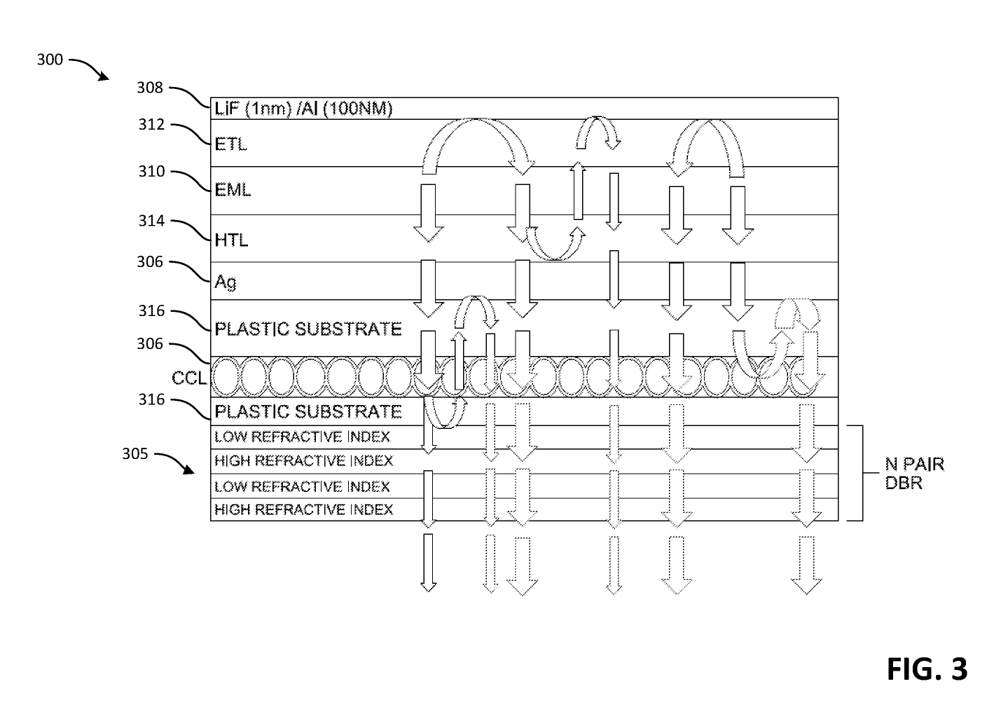

FIG. 3 illustrates a schematic of an OLED device 300 including a luminescent region 302 (also referred to as an OLED), a CCL 304, and a DBR 305. One of skill in the art will understand that a DBR 305 may be used for increasing the upper direction reflectivity. However, the DBR 305 of the configuration in FIG. 3 results in a narrow and more suitable wavelength peak for phosphor conversion. As an example, the DBR 305 may include of periodic structure of two materials with large index of refraction difference, which may offer tunable reflectivity over a certain wavelength region. The DBR 305 may also be configured to operate as a light-recycling filter (LRF) to recycle the backward light from phosphor emission. In the present disclosure, the DBR 305 may include a flexible micro cavity DBR structure, which may be applicable for an OLED device having only a blue emitting layer (e.g., wavelength at about 400 nm to about 480 nm).

The luminescent region 302 may include an anode 306, a cathode 308, an emitting material layer (EML) 310, an electron transport layer (ETL) 312, and a hole transport layer (HTL) 314 arranged in a stacked configuration. The HTL 314 may be configured to transfer the injected holes to the emitting layer. The ETL 312 facilitates the injection and transfer of electrons from the cathode 308. The EML 310 may be configured to combine the holes and electrons and to convert to light energy (e.g., emitted light). The emissive theory of the organic light-emitting diodes is based on injections of electrons and holes, which come from the anode 306 and cathode 308. After recombining within the EML 310, the energy is transferred into visible light. In one aspect, the luminescent region 302 is configured to emit blue light and may be referred to as a blue OLED. For example, the luminescent region 302 emits light in the blue portion of the visible spectrum approximately 400-480 nm. As explained in further detail below, the emission of blue light may be used to produce light in other wavelength ranges.

As illustrated in FIG. 3, the anode 306 may be formed from silver and may have a thickness of about 20 mm. The anode 306 may have a thickness between about 5 nm and about 30 nm, including endpoints within the range. As such, the luminescent region 302 may provide a narrow emission spectrum band due at least in part to the micro cavity effect between the reflective cathode 308 (e.g., Aluminum/Lithium fluoride, about 100 nm Al and about 1 nm LiF) and the silver anode 306. Moreover, the micro cavity effect and resultant narrow emission spectrum may contribute to efficient phosphor excitation, as compared to conventional ITO anodes. Additionally, about half of the converted light emitted backward can be reflected by the anode 306 and extracted out.

The OLED device 300 includes one or more substrates 316 or supporting members. The substrates 316 may be flexible. Each of the substrates 316 may be a flexible substrate composed of an organic solid, an inorganic solid, or a combination of organic and inorganic solids. The substrates 316 may be fabricated as separate individual pieces, such as sheets or wafers, or as a continuous roll. Suitable materials for the substrates 316 include glass, plastic, metal, ceramic, semiconductor, metal oxide, metal nitride, metal sulfide, semiconductor oxide, semiconductor nitride, semiconductor sulfide, carbon, or combinations thereof, or any other materials commonly used to form organic light emitting devices. The substrates 316 may be transparent or light transmissive, light absorbing or light reflective.

One or more of the substrates 316 may be a plastic film. Suitable plastic materials used to form the substrates 316 may include polyetherimide (PEI), polycarbonate (PC), polyethylene terephthalate (PET), polyethylene naphthalate (PEN), polybutylene terephthalate (PBT) or other polyester, polyether sulfone (PES), and polyether ether ketone (PEEK). Other plastic materials, however, may be used to form plastic films for the substrates 316. In some aspects of the disclosure, one or more of the substrates 316 may be a multi-layered plastic film.

The CCL 304 may be arranged to receive light or radiation from the luminescent region 302. The CCL 304 may be disposed on the luminescent region 302, or may be spaced from the luminescent region 302 by one of the substrates 316, as shown in FIG. 3. The CCL 304 is configured to convert at least a portion of the light emitted from the luminescent region 302 to a different color. For example, the present disclosure contemplates that the CCL 304 is configured to produce white light from the emission of non-white light from the luminescent region 302. In one aspect, the color conversion layer produces white light from the blue light emitted from the luminescent region 302.

The CCL 304 may comprise a film of fluorescent or phosphorescent material which efficiently absorbs higher energy photons (e.g. blue light and/or yellow light) and reemits photons at lower energy (e.g. at green and/or red light) depending on the materials used. That is, the CCL 304 may absorb light emitted by an organic light emitting device (e.g. a white OLED) and reemit the light (or segments of the wavelengths of the emission spectrum of the light) at a longer wavelength. For example, if the luminescent region 302 emits blue light in the blue spectral range of 400-480 nm, then the CCL 304 may contain a layer of phosphor material for converting some of this radiation to a different spectral range. Preferably, the phosphor material is configured to convert most or all of the radiation from the luminescent region 302 to the desired spectral range. Phosphor materials suitable for this purpose are generally known in the art and may include, but are not limited to yttrium aluminum garnet (YAG) phosphors.

The phosphor material is typically in the form of a powder. The phosphor powder may be composed of phosphor particles, phosphor microparticles, phosphor nanoparticles or combinations thereof. The phosphor particles or phosphor microparticles may have an average diameter that ranges in size from 1 micron to 100 microns. In one aspect of the present disclosure, the average diameter of the phosphor particles is less than 50 microns. In another aspect of the present disclosure, the average diameter of the phosphor particles is less than 20 microns. In yet another aspect of the present disclosure, the average diameter of the phosphor particles is less than 10 microns. In yet another aspect of the present disclosure, the average diameter of the phosphor nanoparticles used in the phosphor powder ranges from 10 nm to 900 nm. The size of the phosphor particles is generally selected based on the desired thickness of the color conversion layer and/or the overall thickness of the color conversion layer.

The phosphor powder may be dispersed in a binder material that is useful in forming a film or a sheet. A uniform distribution of the phosphor powder in the binder material and throughout the color conversion layer is generally preferred to achieve a consistent color quality of light from the light-emitting device. More uniform color quality and brightness.

The DBR 305 may be disposed adjacent one of the substrates 316 on a side of the substrate 316 opposite the CCL 304. A central peak of wavelength in the DBR 305 may be configured to be about 370 nm, such that at least a portion of blue light passes through without conversion. In certain aspects, a portion of light may be reflected by the DBR 305 and converted by phosphor in the CCL 304, as illustrated by the reflective rays in FIG. 3. The DBR 305 may include of periodic structure of two materials with large index of refraction difference, which may offer tunable reflectivity over a certain wavelength region. As an example, polymer may be used as the low refractive index material and TiO2 as the high refractive index material. Polymer may be is deposited by plasma enhanced CVD (PECVD) and TiO2 may be deposited by sputtering. As a further example, the thickness of polymer is about 75 nm and the thickness of the TiO2 is about 33 nm, which may be configured to correspond to a quarter of the central wavelength.

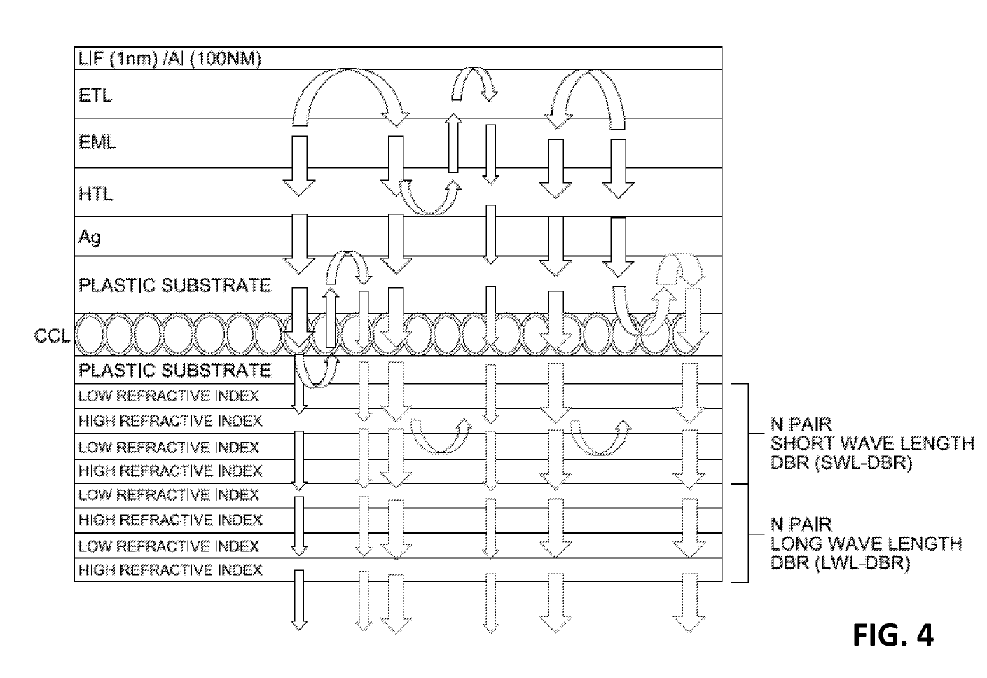

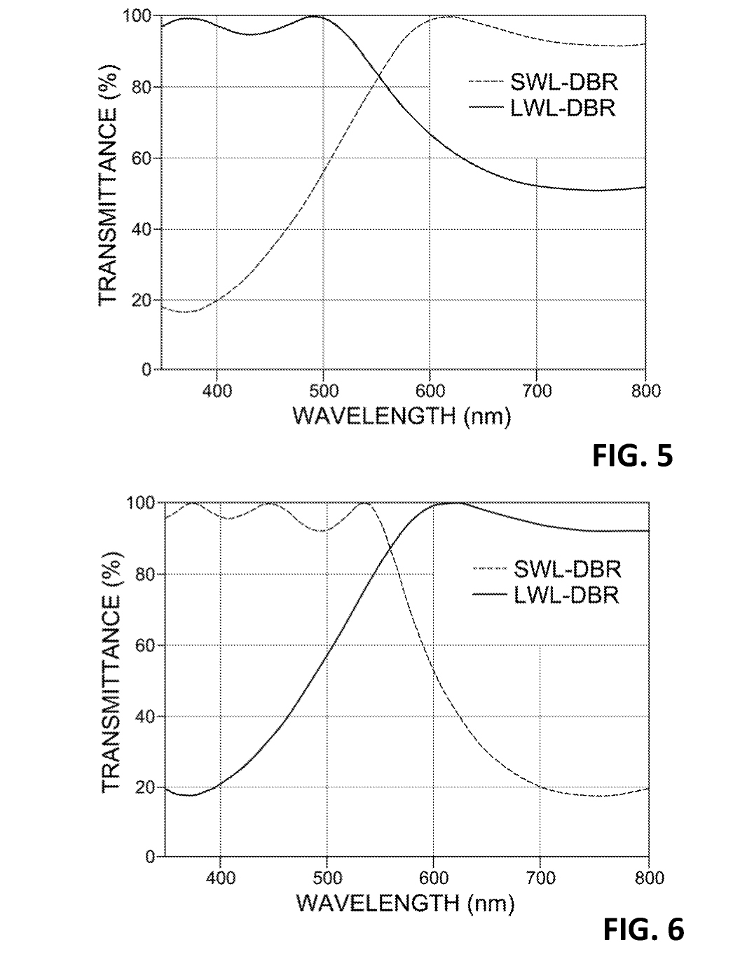

In certain aspects, higher color rendering index (CRI) value of white OLED may be achieved by depositing another DBR layer, as shown in FIG. 4. The total transmittance of the DBR layer(s) may be tuned by adjusting a number of pairs of each DBR (short wavelength (SWL)-DBR, long wavelength (LWL)-DBR, etc.) to a spectrum of natural sunlight. As an illustrative example, FIGS. 5-6 show two types of DBR combination (SWL, LWL-DBR), where the central wavelength of SWL-DBR is 370 nm and LWL-DBR is 750 nm. The only difference between two graphs in FIGS. 5-6 is number of pair of LWL.

Fabrication

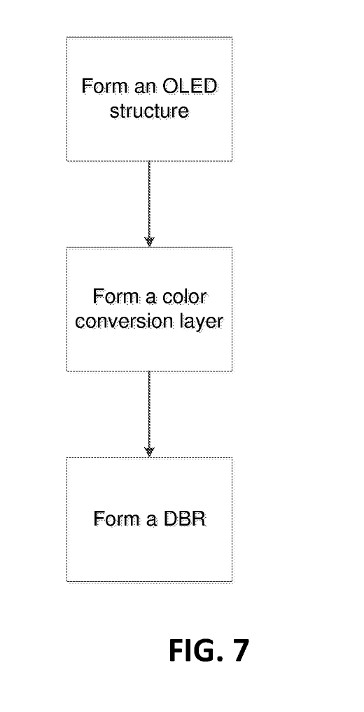

FIG. 7 is a block diagram describing the process steps of fabricating an OLED assembly 10 according to an aspect of the disclosure. The process 700 may begin with step 710 by forming an OLED structure, including providing a flexible substrate, providing an OLED on the flexible substrate, wherein the OLED comprises a first electrode, a second electrode and an organic electroluminescent layer disposed between the first and second electrodes. As an example, at least one of the first and second electrodes is formed form silver or aluminum. As a further example, the OLED structure is configured to emit a first color light within a first wavelength range and the color conversion layer is configured to convert at least a portion of the first color light emitted from the OLED to a second color within a second wavelength range. Step 720 may include forming a color conversion layer adjacent a side of the flexible substrate opposite the OLED. Step 730 may include forming a distributed bragg reflector (DBR) adjacent the color conversion layer. In an aspect, the DBR comprises a polymeric layer disposed adjacent a layer of titanium dioxide. As an example, the polymeric layer is formed using chemical vapor deposition. As a further example, the layer of titanium dioxide is formed using sputtering.

It will be appreciated that the foregoing description provides examples of the disclosed system and technique. However, it is contemplated that other implementations of the disclosure may differ in detail from the foregoing examples. All references to the disclosure or examples thereof are intended to reference the particular example being discussed at that point and are not intended to imply any limitation as to the scope of the disclosure more generally. All language of distinction and disparagement with respect to certain features is intended to indicate a lack of preference for those features, but not to exclude such from the scope of the disclosure entirely unless otherwise indicated.

### Definitions

It is to be understood that the terminology used herein is for the purpose of describing particular aspects only and is not intended to be limiting. As used in the specification and in the claims, the term “comprising” can include the embodiments “consisting of” and “consisting essentially of.” Unless defined otherwise, all technical and scientific terms used herein have the same meaning as commonly understood by one of ordinary skill in the art to which this disclosure belongs. In this specification and in the claims which follow, reference will be made to a number of terms which shall be defined herein.

As used in the specification and the appended claims, the singular forms “a,” “an” and “the” include plural equivalents unless the context clearly dictates otherwise. Thus, for example, reference to “a polycarbonate polymer” includes mixtures of two or more polycarbonate polymers.

As used herein, the term “combination” is inclusive of blends, mixtures, alloys, reaction products, and the like.

Ranges can be expressed herein as from one particular value to another particular value. When such a range is expressed, another aspect includes from the one particular value and/or to the other particular value. Similarly, when values are expressed as approximations, by use of the antecedent ‘about,’ it will be understood that the particular value forms another aspect. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed. It is also understood that each unit between two particular units are also disclosed. For example, if 10 and 15 are disclosed, then 11, 12, 13, and 14 are also disclosed.

As used herein, the terms “about” and “at or about” mean that the amount or value in question can be the value designated some other value approximately or about the same. It is generally understood, as used herein, that it is the nominal value indicated ±5% variation unless otherwise indicated or inferred. The term is intended to convey that similar values promote equivalent results or effects recited in the claims. That is, it is understood that amounts, sizes, formulations, parameters, and other quantities and characteristics are not and need not be exact, but can be approximate and/or larger or smaller, as desired, reflecting tolerances, conversion factors, rounding off, measurement error and the like, and other factors known to those of skill in the art. In general, an amount, size, formulation, parameter or other quantity or characteristic is “about” or “approximate” whether or not expressly stated to be such. It is understood that where “about” is used before a quantitative value, the parameter also includes the specific quantitative value itself, unless specifically stated otherwise.

Disclosed are the components to be used to prepare the compositions of the disclosure as well as the compositions themselves to be used within the methods disclosed herein. These and other materials are disclosed herein, and it is understood that when combinations, subsets, interactions, groups, etc. of these materials are disclosed that while specific reference of each various individual and collective combinations and permutation of these compounds cannot be explicitly disclosed, each is specifically contemplated and described herein. For example, if a particular compound is disclosed and discussed and a number of modifications that can be made to a number of molecules including the compounds are discussed, specifically contemplated is each and every combination and permutation of the compound and the modifications that are possible unless specifically indicated to the contrary. Thus, if a class of molecules A, B, and C are disclosed as well as a class of molecules D, E, and F and an example of a combination molecule, A-D is disclosed, then even if each is not individually recited each is individually and collectively contemplated meaning combinations, A-E, A-F, B-D, B-E, B-F, C-D, C-E, and C-F are considered disclosed. Likewise, any subset or combination of these is also disclosed. Thus, for example, the sub-group of A-E, B-F, and C-E would be considered disclosed. This concept applies to all aspects of this application including, but not limited to, steps in methods of making and using the compositions of the disclosure. Thus, if there are a variety of additional steps that can be performed it is understood that each of these additional steps can be performed with any specific aspect or combination of aspects of the methods of the disclosure.

As used herein, the term “transparent” means that the level of transmittance for a disclosed composition is greater than 50%. In some embodiments, the transmittance can be at least 60%, 70%, 80%, 85%, 90%, or 95%, or any range of transmittance values derived from the above exemplified values. In the definition of “transparent”, the term “transmittance” refers to the amount of incident light that passes through a sample measured in accordance with ASTM D1003 at a thickness of 3.2 millimeters.

The term “adhesive” as used herein refers to a sticky, gluey or tacky substance capable of adhering two films together. In preferred embodiments, the adhesive is transparent. In the adhesive, desiccant material can be added for improving WVTR property. Ultraviolet (UV) or thermal energy may be necessary for curing adhesive layer.

Unless otherwise stated to the contrary herein, all test standards are the most recent standard in effect at the time of filing this application.

### Aspects

The present disclosure comprises at least the following aspects.

Aspect 1. A light-emitting device comprising: a substrate; an organic light emitting diode (OLED) disposed adjacent the substrate, the OLED configured to emit light having a wavelength at about 400 nm to about 480 nm; a color conversion layer disposed adjacent a side of the substrate opposite the OLED; and a distributed Bragg reflector (DBR) disposed adjacent the color conversion layer.

Aspect 2. The light-emitting device of aspect 1, wherein the OLED comprises a metallic anode having a thickness of between about 5 nm and about 30 nm.

Aspect 3. The light-emitting device of aspect 2, wherein the metallic anode is formed form silver.

Aspect 4. The light-emitting device of any of aspects 1-3, wherein the color conversion layer is configured to convert at least a portion of the light emitted from the OLED to a second color range outside of the range including wavelengths from about 400 nm to about 480 nm.

Aspect 5. The light-emitting device of any of aspects 1-4, wherein the DBR is flexible.

Aspect 6. The light-emitting device of any of aspects 1-5, wherein the DBR comprises inorganic and organic layers.

Aspect 7. The light-emitting device of any of aspects 1-6, further comprising a capping layer disposed adjacent the cathode.

Aspect 8. The light-emitting device of any of aspects 1-7, wherein the capping layer comprises tungsten oxide.

Aspect 9. The light-emitting device of any of aspects 1-8, wherein the central peak of wavelength in the DBR is about 370 nm.

Aspect 10. The light-emitting device of any of aspects 1-9, wherein the central peak of wavelength in the DBR is about 740 nm.

Aspect 11. The light-emitting device of any of aspects 1-10, wherein the DBR comprises layers having alternating indexes of refraction.

Aspect 12. The light-emitting device of any of aspects 1-11, wherein the DBR comprises a polymeric layer disposed adjacent a layer of titanium dioxide.

Aspect 13. The light-emitting device of aspect 12, wherein the polymeric layer has a thickness of about 75 nm.

Aspect 14. The light-emitting device of aspect 12, wherein the layer of titanium dioxide has a thickness of about 33 nm.

Aspect 15. A process of fabricating an OLED assembly comprising: forming an OLED structure, including providing a flexible substrate, providing an OLED on the flexible substrate, wherein the OLED comprises a first electrode, a second electrode and an organic electroluminescent layer disposed between the first and second electrodes; forming a color conversion layer adjacent a side of the flexible substrate opposite the OLED; and forming a distributed bragg reflector (DBR) adjacent the color conversion layer.

Aspect 16. The process of aspect 15, wherein at least one of the first and second electrodes is formed form silver and has a thickness of between about 5 nm and about 30 nm.

Aspect 17. The process of any of aspects 15-16, wherein the OLED structure is configured to emit a first color light within a first wavelength range and the color conversion layer is configured to convert at least a portion of the first color light emitted from the OLED to a second color within a second wavelength range.

Aspect 18. The process of any of aspects 15-17, wherein the DBR comprises a polymeric layer disposed adjacent a layer of titanium dioxide.

Aspect 19. The process of aspect 18, wherein the polymeric layer is formed using chemical vapor deposition.

Aspect 20. The process of aspect 18, wherein the layer of titanium dioxide is formed using sputtering.

1. A light-emitting device comprising:
a substrate;
an organic light emitting diode (OLED) disposed adjacent the substrate, the OLED configured to emit light having a wavelength at about 400 nm to about 480 nm;
a color conversion layer disposed adjacent a side of the substrate opposite the OLED; and
a Distributed Bragg Reflector (DBR) disposed adjacent the color conversion layer.

2. The light-emitting device of claim 1, wherein the OLED comprises a metallic anode having a thickness of between about 5 nm and about 30 nm.

3. The light-emitting device of claim 2, wherein the metallic anode is formed form silver.

4. The light-emitting device of claim 1, wherein the color conversion layer is configured to convert at least a portion of the light emitted from the OLED to a second color range outside of the range including wavelengths from about 400 nm to about 480 nm.

5. The light-emitting device of claim 1, wherein the DBR is flexible.

6. The light-emitting device of claim 1, wherein the DBR comprises inorganic and organic layers.

7. The light-emitting device of claim 1, further comprising a capping layer disposed adjacent the cathode.

8. The light-emitting device of claim 1, wherein the capping layer comprises tungsten oxide.

9. The light-emitting device of claim 1, wherein the central peak of wavelength in the DBR is about 370 nm.

10. The light-emitting device of claim 1, wherein the central peak of wavelength in the DBR is about 740 nm.

11. The light-emitting device of claim 1, wherein the DBR comprises layers having alternating indexes of refraction.

12. The light-emitting device of claim 1, wherein the DBR comprises a polymeric layer disposed adjacent a layer of titanium dioxide.

13. The light-emitting device of claim 12, wherein the polymeric layer has a thickness of about 75 nm.

14. The light-emitting device of claim 12, wherein the layer of titanium dioxide has a thickness of about 33 nm.

15. A process of fabricating an OLED assembly comprising:
(a) forming an OLED structure, including providing a flexible substrate, providing an OLED on the flexible substrate, wherein the OLED comprises a first electrode, a second electrode and an organic electroluminescent layer disposed between the first and second electrodes;
(b) forming a color conversion layer adjacent a side of the flexible substrate opposite the OLED; and
(c) forming a Distributed Bragg Reflector (DBR) adjacent the color conversion layer.

16. The process of claim 15, wherein at least one of the first and second electrodes is formed form silver and has a thickness of between about 5 nm and about 30 nm.

17. The process of claim 15, wherein the OLED structure is configured to emit a first color light within a first wavelength range and the color conversion layer is configured to convert at least a portion of the first color light emitted from the OLED to a second color within a second wavelength range.

18. The process of claim 15, wherein the DBR comprises a polymeric layer disposed adjacent a layer of titanium dioxide.

19. The process of claim 18, wherein the polymeric layer is formed using chemical vapor deposition.

20. The process of claim 18, wherein the layer of titanium dioxide is formed using sputtering.
